(19) United States
(12) Patent Application Publication
(10) Pub. No.: US 2012/0128892 A1
(43) Pub. Date: May 24, 2012

(54) SURFACE PROCESSING METHOD AND SURFACE PROCESSING APPARATUS

(75) Inventors: Noriaki TOYODA, Hyogo (JP); Isao Yamada, Hyogo (JP); Masaki Narushima, Yamanashi (JP); Masayuki Harashima, Yamanashi (JP); Eisuke Morisaki, Yamanashi (JP)

(73) Assignees: Tokyo Electron Limited, Tokyo (JP); HYOGO PREFECTURE, Hyogo (JP)

(21) Appl. No.: 13/114,096

(22) Filed: May 24, 2011

(30) Foreign Application Priority Data
May 26, 2010 (JP) 2010-120920

(51) Int. Cl. C23C 16/02; C23C 16/34

(52) U.S. Cl. 427/523; 118/723 R

(57) ABSTRACT

A disclosed surface processing method includes a first processing step, wherein a gas cluster beam is generated from a source material that does not contain nitrogen, and irradiated to a member to be processed, and a second processing step, wherein a nitrogen gas cluster beam is generated and irradiated to the member to be processed.

### CROSS-REFERENCE TO RELATED APPLICATION

The present application is based on Japanese Priority Application No. 2010-120920 filed on May 26, 2010, the entire contents of which are hereby incorporated herein by reference.

### BACKGROUND OF THE INVENTION

1. Field of the Invention

The present invention relates to a surface processing method and surface processing apparatus.

2. Description of the Related Art

Gas clusters into which plural atoms and the like are condensed exhibit a unique physicochemical behavior, and attract attention for applications in various fields of technologies. Namely, gas cluster ion beams are thought to be applicable for processes such as ion-implantation, surface machining, and thin film deposition in a depth range of several nanometers from a surface of a solid material, while the processes in such a depth range have been considered difficult by conventional technologies.

In a gas cluster generating apparatus, it is possible to generate gas clusters formed of several hundred through several thousand atoms from a compressed gas supplied from a gas supplying source. Because the gas clusters so-generated provide a significant effect for planarizing a surface of a substrate or the like, various investigations have been carried out.

Patent Document 1: Japanese Patent Application Laid-Open Publication No. 2008-227283.

Incidentally, a highly planarized surface of a substrate is required along with an enhanced demand for further miniaturization and higher integration in a semiconductor fabrication. For example, because a surface planarization process using oxygen or sulfur hexafluoride (SF₆) gas clusters has its limitation in terms of a degree of planarity, it is difficult to obtain a desirably flatter surface using such a process. In addition, when a chemical mechanical polishing (CMP) is carried out with respect to a surface of a substrate or the like that is made of a hard material, there remain a lot of scratches in the polished surface, and such a surface may be difficult to be further planarized in order to remove scratches.

The present invention has been made in view of the above, and provides a surface processing method and a surface processing apparatus that are capable of planarizing a surface of a substrate or the like, thereby obtaining a surface with extremely high planarity.

### SUMMARY OF THE INVENTION

According to a first aspect of the present invention, there is provided a surface processing method including a first processing step, wherein a gas cluster beam is generated from a source material that does not contain nitrogen, and irradiated to a member to be processed, and a second processing step, wherein a nitrogen gas cluster beam is generated and irradiated to the member to be processed.

The surface processing method according to the first aspect may further include a chemical mechanical polishing step, wherein a chemical mechanical polishing is carried out prior to the first processing step with respect to the member to be processed.

In the surface processing method according to the first aspect, the source material that does not include nitrogen comprises one or more of argon, oxygen, carbon dioxide, water, sulfur hexafluoride, nitrogen trifluoride, and xenon.

In the surface processing method according to the first aspect, the nitrogen gas cluster beam in the second processing step does not include a gas cluster originating from the source material in the first processing step.

In the surface processing method according to the first aspect, the member to be processed comprises one or more of silicon carbide, silicon, quartz, glass, alumina, sapphire, gallium nitride, gallium arsenide, diamond-like carbon, boron carbide, and poly-crystalline diamond.

The surface processing method according to the first aspect may further include a third processing step, wherein another nitrogen gas cluster beam is irradiated at a lower acceleration voltage than an acceleration voltage in the second processing step to the member to be processed, after the second processing step.

The surface processing method according to the first aspect may further include a third processing step, wherein another gas cluster beam that has a gas cluster having a larger size than a size of the nitrogen gas cluster in the nitrogen gas cluster beam in the second processing step is irradiated to the member to be processed, after the second processing step.

According to a second aspect of the present invention, there is provided a surface processing apparatus where a gas cluster beam is irradiated to a member to be processed. This surface processing apparatus includes a nozzle that generates the gas cluster beam: a source gas supplying portion that includes a first gas supplying source that supplies a source material that does not include nitrogen, and a second source gas supplying source that supplies nitrogen gas; and a control portion that causes the source gas supplying portion to selectively supply the source material and the nitrogen gas, and controls the selected source gas from the source gas supplying portion.

In the surface processing apparatus according to the second aspect, the source material includes one or more of argon, oxygen, carbon dioxide, water, sulfur hexafluoride, nitrogen trifluoride, and xenon.

In the surface processing apparatus according to the second aspect, the nitrogen gas in the second source gas supplying source does not include the source material that does not include nitrogen in the first source gas supplying source.

In the surface processing apparatus according to the second aspect, the member to be processed comprises one or more of silicon carbide, silicon, quartz, glass, alumina, sapphire, gallium nitride, gallium arsenide, diamond-like carbon, boron carbide, an poly-crystalline diamond.

The surface processing apparatus according to the second aspect may further include an ionizing portion that ionizes the gas cluster beam from the nozzle; an acceleration portion that accelerates the ionized gas cluster beam; an acceleration voltage supplying portion that supplies an acceleration voltage to the acceleration portion; and an acceleration voltage controlling portion that controls the acceleration voltage supplying portion so that the gas cluster beam can be irradiated to the member to be processed at different voltages.

The surface processing apparatus according to the second aspect may further include an electrode portion that selects a gas cluster having a desired size; and an electric power source that supplies an electric voltage to the electrode portion so that gas cluster beam having a gas cluster having a desired size is selected.

### BRIEF DESCRIPTION OF THE DRAWINGS

FIG. 1 is a schematic view of a surface processing apparatus according to a first embodiment of the present invention;

FIG. 2 is a flowchart of a surface processing method according to the first embodiment of the present invention;

FIG. 3 illustrates an atomic force microscope image of a substrate surface processed by the surface processing method according to the first embodiment of the present invention;

FIG. 4 illustrates another atomic force microscope image of a substrate surface processed by the surface processing method according to the first embodiment of the present invention;

FIG. 5 illustrates yet another atomic force microscope image of a substrate surface processed by the surface processing method according to the first embodiment of the present invention;

FIG. 6 illustrates a relationship between an attenuation constant and energy per atom in gas clusters;

FIG. 7 is a flowchart of a surface processing method according to a second embodiment of the present invention; and

FIG. 8 is an atomic force microscope image of a substrate surface processed by the surface processing method according to the second embodiment of the present invention.

### DETAILED DESCRIPTION OF THE PREFERRED EMBODIMENT

According to an embodiment of the present invention, there is provided a surface processing method and a surface processing apparatus that are capable of planarizing a surface of a substrate or the like, thereby obtaining a surface with extremely high planarity.

### First Embodiment

(Surface Processing Apparatus)

First, a surface processing apparatus to be used in a surface processing method according to a first embodiment of the present invention is explained. The surface processing apparatus is a gas cluster beam irradiation apparatus that can irradiate a gas cluster beam onto a surface of a substrate or the like.

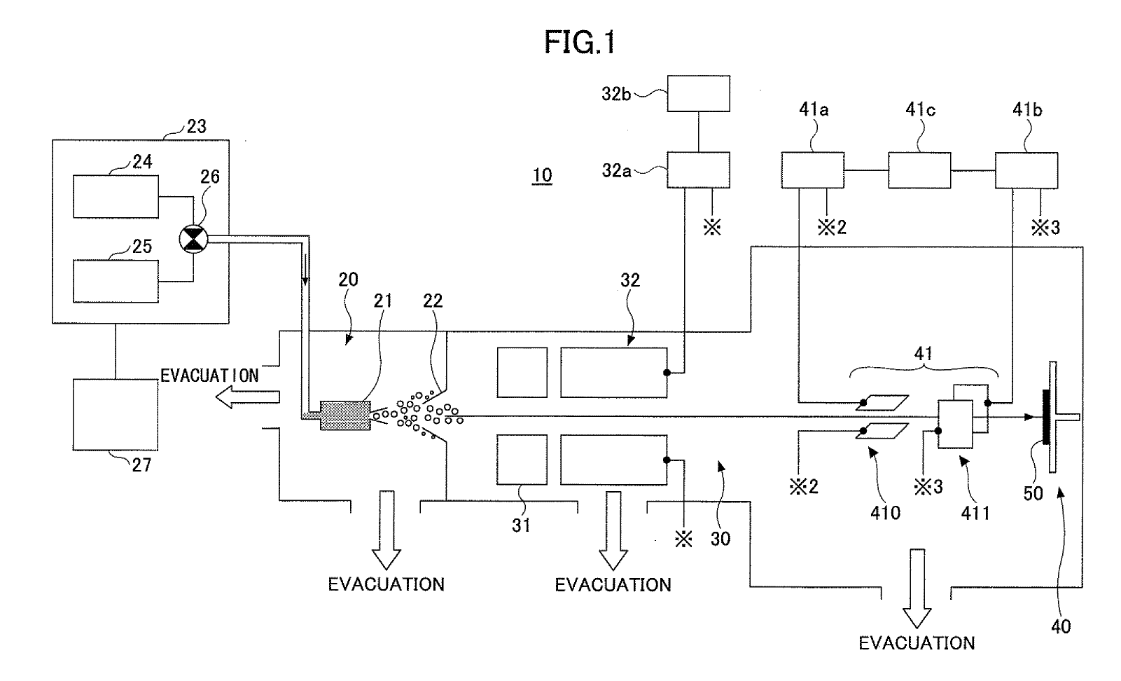

FIG. 1 schematically illustrates a gas cluster beam irradiation apparatus. As shown, a gas cluster beam irradiation apparatus 10 is provided with a nozzle chamber 20, a source chamber 30, and a main chamber 40. The nozzle chamber 20 is provided with a nozzle 21 that generates gas clusters, and a skimmer 22 that selects the generated gas clusters. The nozzle 21 is connected to a gas supplying portion 23, so that a source gas is supplied to the nozzle 21 from the gas supplying portion 23, thereby generating the gas clusters. The gas supplying portion 23 includes plural gas supplying sources so that plural source gases can be supplied to the nozzle 21. Specifically, the gas supplying portion 23 is provided with a first gas supplying source 24 and a second gas supplying source 25, which are, for example, gas cylinders filled with a source gas. In addition, the gas supplying portion 23 includes a valve 26, so that the gas in the first gas supplying source 24 and the gas in the second gas supplying source 25 are selectively supplied to a flow rate controlling valve 21. In this embodiment, an argon gas cylinder is used as the first gas supplying source 24, and a nitrogen gas cylinder is used as the second gas supplying source 25. In addition, a controlling portion 27 is connected to the gas supplying portion 23, and thus the source gas is supplied from the first gas supplying source 24 or the second gas supplying source 25 under control of the controlling portion 27.

The gas clusters generated in the nozzle 21 are selected by the skimmer 22, and the selected gas clusters are introduced into the source chamber 30. The source chamber is provided with an ionizing portion 31 that ionizes gas clusters, so that the gas clusters introduced into the source chamber 30 are ionized by the ionizing portion 31, and the ionized gas clusters are accelerated by an acceleration portion 32. The acceleration portion 32 is connected to an acceleration voltage source 32a that supplies an acceleration voltage to the acceleration portion 32, and the acceleration voltage source 32a is connected to a controller 32b that controls the acceleration voltage source 32a.

Then, gas clusters having a desired size are selected from the accelerated ionized gas clusters by an electrode portion 41 provided in the main chamber 40, and the selected gas clusters are irradiated to a to-be-processed member 50 such as a substrate or the like. The electrode portion 41 includes a pair of electrode plates 410 that face each other along a first direction and a pair of electrode plates 411 that face each other in a second direction orthogonal to the first direction. In addition, electric power sources 41a, 41b are connected to the electrode plates 410 and the electrode plates 411, respectively. Moreover, an electrode voltage controlling portion 41c is connected to electric power sources 41a, 41b in order to supply voltage to the electrodes 410, 411. With such a configuration, an electromagnetic field is generated across the electrode plates 410 in the first direction by applying a voltage from the electric power source 41a under control of the electrode voltage controlling portion 41c, and another electric field is generated across the electrode plates 411 in the second direction by applying a voltage from the electric power source 41b under control of the electrode voltage controlling portion 41c. By changing the voltages applied to the electrode plates 410, 411, the gas clusters having a desired size can pass through the electrode plates 410, 411, thereby being irradiated to the to-be-processed member 50.

Incidentally, the source gas is compressed up to several atoms and supplied to the nozzle 21 in the gas cluster beam irradiation apparatus according to this embodiment. Therefore, the compressed source gas is jetted from the nozzle 21 into the nozzle chamber 20 that has been kept at vacuum, and thus the source gas is subject to adiabatic expansion so that the source gas is rapidly cooled. As a result, the gas clusters with extremely weak interatomic or intermolecular force are generated.

(Surface Processing Method)

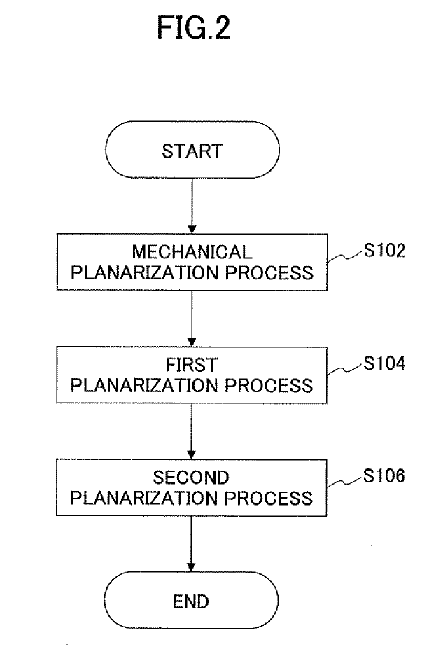

Next, a surface processing method according to an embodiment of the present invention is explained with reference to FIG. 2. In this embodiment, a silicon carbide (SiC) substrate is used as the to-be-processed member 50, and a case where a surface of the SiC substrate is planarized is explained. Incidentally, SiC is harder than alumina or the like, followed by only diamond and boron carbide in terms of hardness, and known as one of materials that are difficult to be planarized.

First, the surface of the SiC substrate is polished by a CMP process at Step S102, which makes the surface fully planarized to the naked eye. However, countless micro-scratches that cannot be recognized with the naked eye are made in the flat surface of the SIC substrate. Namely, such scratches cannot be avoided by a polishing method such as the CMP process in the case of a hard material such as SiC.

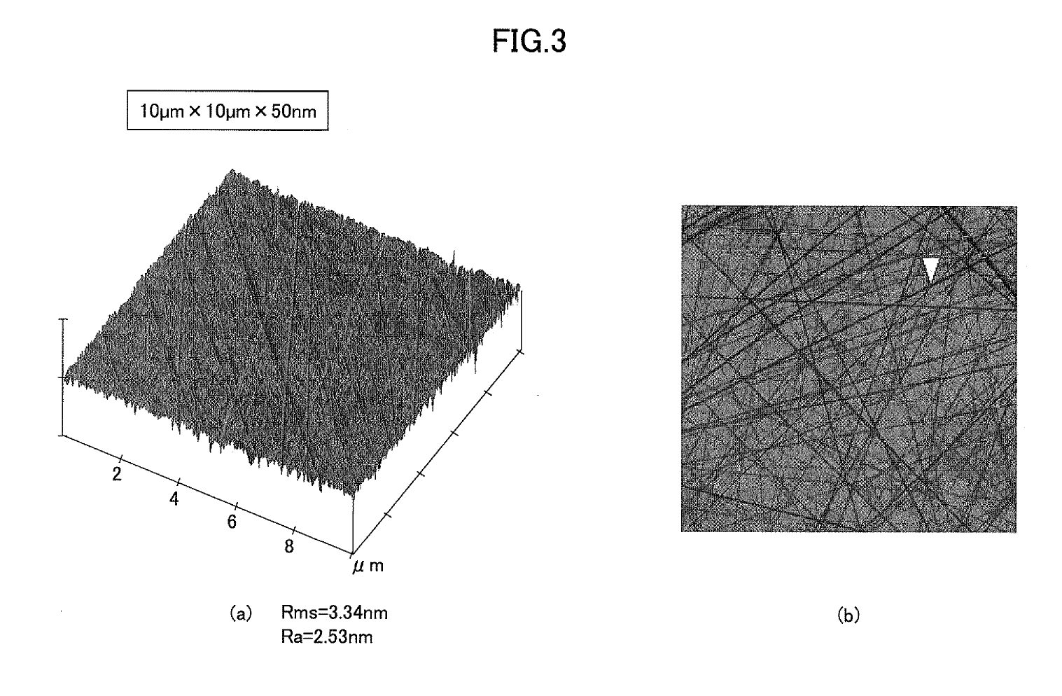

FIG. 3 illustrates a result of an atomic force microscope (AFM) observation for the surface of the SIC substrate that has been polished by the CMP process. Incidentally, an atomic microscope is an instrument that probes force caused between a probing needle and a surface to be observed, by use of the deflection of a cantilever provided at the distal end of the probing needle or deviation from a resonant frequency of the probing needle (translation of an excerpt from a “scanning probe microscope” section of Rikagaku-jiten (physical and chemical science dictionary), 5th version, Iwanami shoten (Publisher)). FIG. 3(a) is a perspective view and FIG. 3(b) is a plan view of the surface of the SiC substrate. As shown, a countless number of scratches are observed. Note that arrows in FIG. 3(b) indicate relatively large scratches. As far as surface roughness in an area of a square having sides of 10 μm is concerned, Rms (root mean square roughness) and Ra (average roughness) are equal to 3.34 nm and 2.53 nm, respectively, which indicates that the surface of the SIC substrate is not highly planarized.

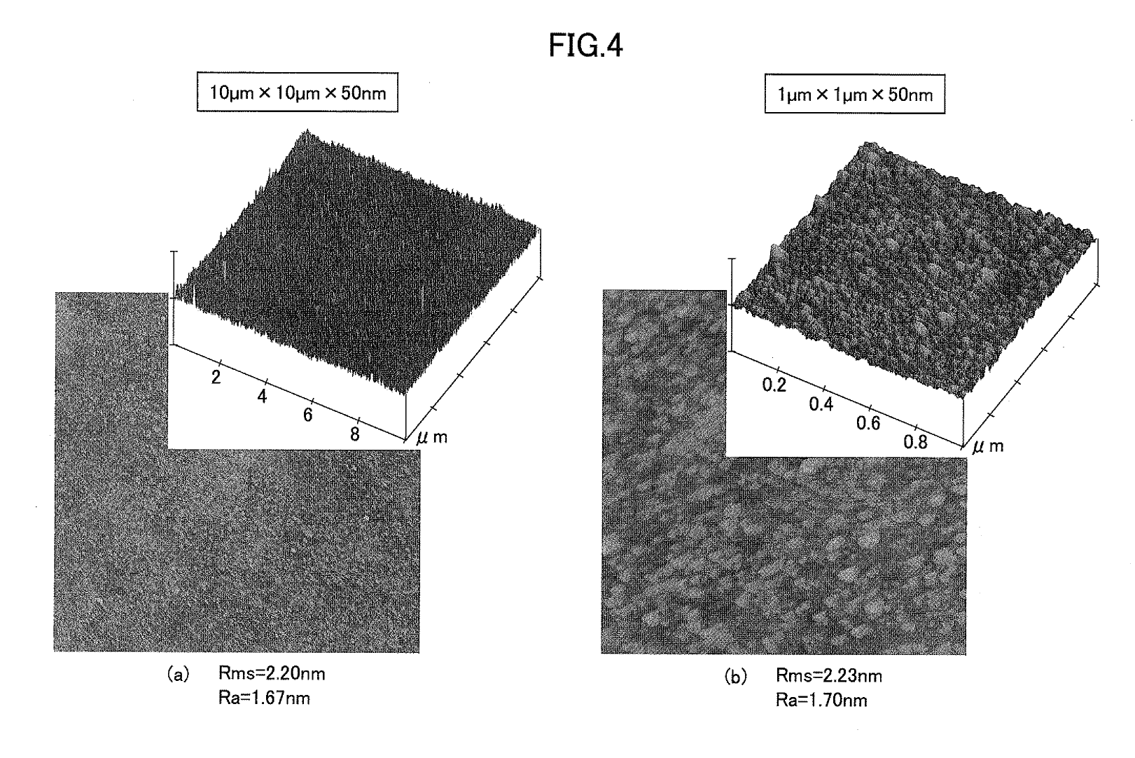

Next, the Ar gas clusters are irradiated on the surface of the SiC substrate that has been subject to the CMP process, at Step S104 as a first planarization process. FIG. 4 illustrates a result of an AFM observation for the surface of the SiC substrate that has been subject to the Ar gas cluster irradiation. FIG. 4(a) illustrates an area of a square having sides of 10 μm and FIG. 4(b) illustrates an area of a square having sides of 1 μm. As shown, the scratches that have been caused by the CMP process are removed by irradiating the Ar gas clusters. Specifically, Rms and Ra are 2.20 nm and 1.67 nm, respectively, in the case of the area of the square having sides of 10 μm, and 2.23 nm and 1.70 nm, respectively, in the case of the area of the square having sides of 10 μm. Therefore, an extremely flat surface is obtained on the SiC substrate.

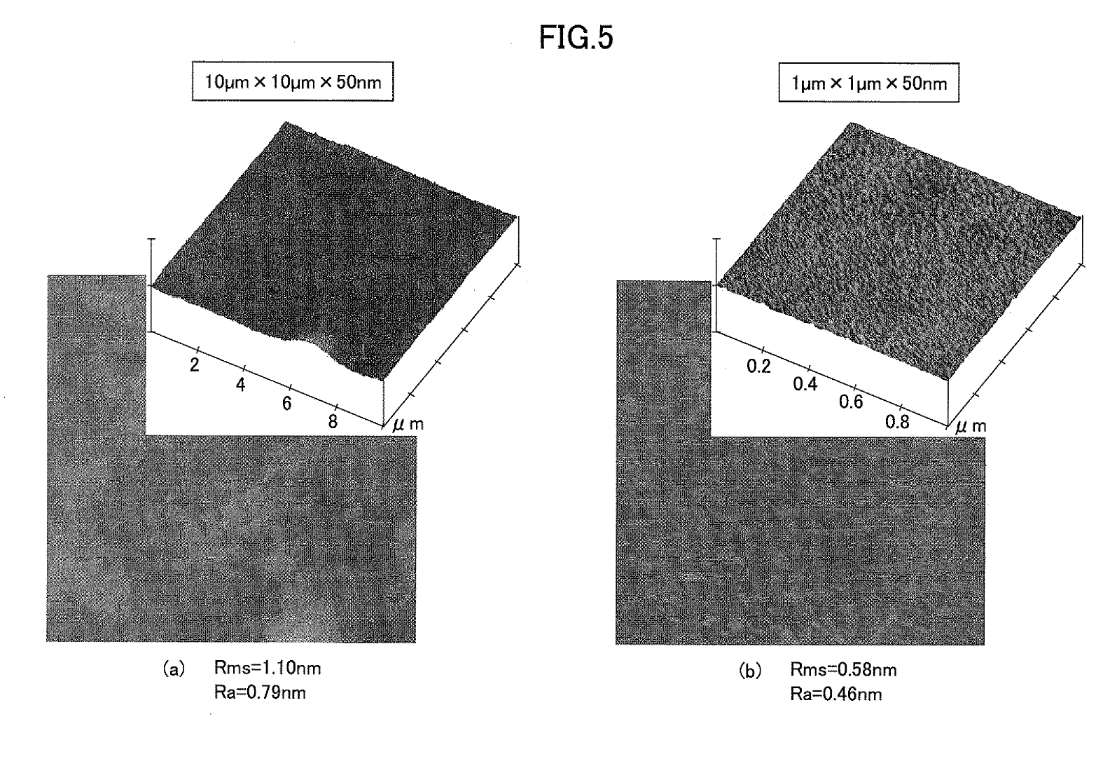

Next, the nitrogen gas clusters are irradiated to the surface of the SiC substrate that has been subject to the Ar gas cluster irradiation at Step S106 as a second planarization process. FIG. 5 illustrates a result of an AFM observation for the surface of the SiC substrate that has been subject to the nitrogen gas cluster irradiation. FIG. 4(a) illustrates an area of a square having sides of 10 μm and FIG. 4(b) illustrates an area of a square having sides of 1 μm. As shown, the surface of the SiC substrate can be more planarized than that right after irradiating the Ar gas clusters onto the surface of the SIC substrate. After the nitrogen gas irradiation, Rms and Ra are 1.10 nm and 0.79 nm, respectively, in the case of the area of the square having sides of 10 μm, and 0.58 nm and 0.46 nm, respectively, in the case of the area of the square having sides of 10 μm.

In such a manner, because the first planarization process using the Ar gas clusters and the second planarization process using the nitrogen gas clusters are carried out in this order after the CMP process, the surface of the SiC substrate can be more planarized, compared to a case where only the Ar gas clusters are used after the CMP process in order to planarize the surface of the SiC substrate. While only the nitrogen gas clusters may be used after the CMP process, it takes a longer time to planarize the surface of the SIC substrate. Therefore, use of the Ar gas clusters and the nitrogen gas clusters is preferable.

In the surface processing method according to this embodiment, the surface of the SiC substrate is planarized first using the Ar gas clusters in the first planarization process and then using the nitrogen gas clusters in the second planarization process. The planarization process using the Ar gas clusters may serve as coarse planarization suitable to remove scratches caused by the CMP process, and the planarization using the nitrogen gas clusters may serve as relatively fine planarization.

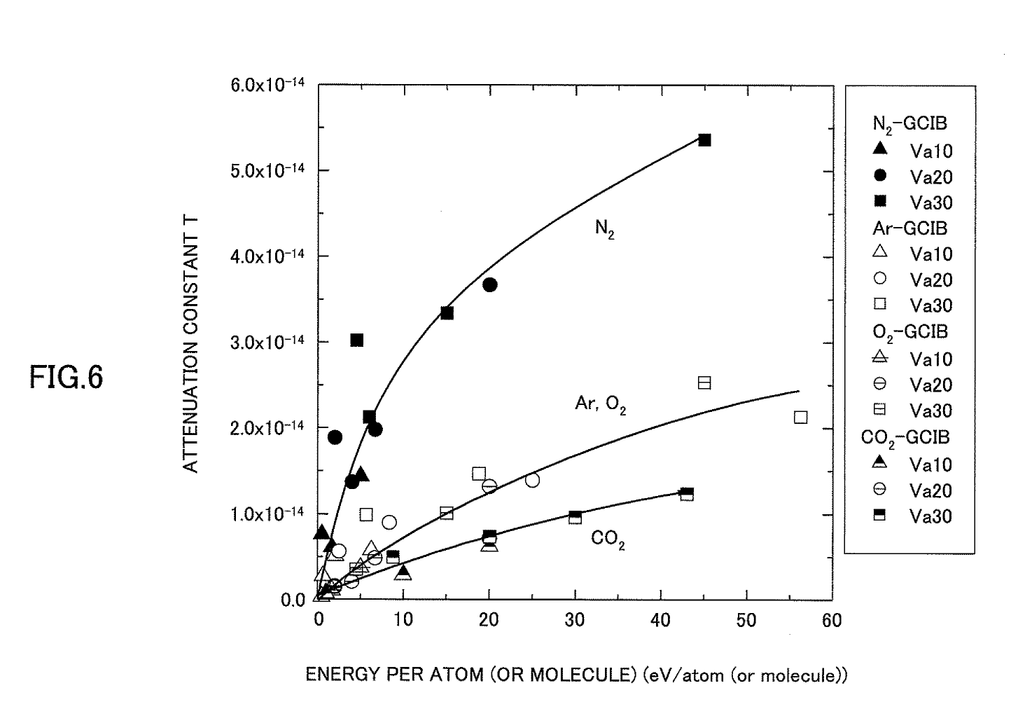

This can be explained in the following manner, with reference to FIG. 6. FIG. 6 illustrates a relationship between energy per atom and attenuation constant, which indicates fragileness of each gas cluster. In FIG. 6, Va30 indicates an acceleration voltage of 30 kV; Va20 indicates an acceleration voltage of 20 kV; and Va10 indicates an acceleration voltage of 10 kV. As shown, the nitrogen gas clusters have a higher attenuation constant than that of the Ar gas clusters, which means that the nitrogen gas clusters are easily broken. Therefore, it may be thought that when the nitrogen gas clusters collide with the surface of the SiC substrate, the nitrogen gas clusters are broken. In other words, the nitrogen gas clusters collide with the surface of the SiC substrate at relatively lower energy, so that slight roughness caused after the irradiation of the Ar clusters onto the surface of the SIC substrate can be planarized.

On the other hand, because the Ar gas clusters are not very easily broken, the Ar gas clusters collide with the surface of the SiC substrate at relatively higher energy. Therefore, while the scratches caused by the CMP process can be removed by the irradiation of the Ar gas clusters onto the surface of the SIC substrate, it is difficult to further planarize the surface.

Therefore, the scratches caused in the surface of the SiC substrate by the CMP process can be removed and in addition the surface can be further planarized by carrying out the first planarization process using the Ar gas clusters and then the second planarization process using the nitrogen gas clusters.

In such a manner, it may be thought that there is a relationship between the planarity of the surface that goes through the planarization process using the gas clusters and the attenuation constant of the gas clusters used, and gas clusters having a larger attenuation constant are suitable for planarizing a roughly planarized surface into a finely planarized surface.

Therefore, the gas clusters having a first attenuation constant are used to planarize the surface of the substrate in the first planarization process, and then the gas clusters having a second attenuation constant higher than the first attenuation constant are used to planarize the surface of the substrate in the second planarization process, thereby improving the planarity of the surface of the substrate.

As other gas clusters that have a similar attenuation constant as the Ar gas clusters, there are oxygen gas clusters. As other gas clusters having a lower attenuation constant than that of the Ar gas clusters, there are carbon dioxide (CO₂) gas clusters.

In addition, the nitrogen gas clusters is one of the gas clusters that have the lowest attenuation constant among practically usable gas clusters. Therefore, when plural planarization processes using gas clusters are carried out, the nitrogen gas clusters are preferably used in the last planarization process.

Incidentally, as materials that are suitably used to carry out the first planarization process, there are water (H₂O), sulfur hexafluoride (SF₆), nitrogen trifluoride (NF₃), xenon (Xe) or the like, in addition to argon, oxygen, and carbon dioxide in the surface processing method according to this embodiment.

In addition, nitrogen is preferable as a material to be used to carry out the second planarization process. Especially, it is preferable that the material to be used to carry out the second planarization process does not include a material to be used to carry out the first planarization process.

As a material of the substrate or the like subject to the surface processing method, there may be silicon, quartz, glass, alumina, sapphire, gallium nitride, gallium arsenide, diamond-like carbon, boron carbide, poly-crystalline diamond, or the like, in addition to SIC. Especially, the surface processing method is suitable for planarizing a hard material.

In addition, the to-be-processed member 50 that is subject to the surface processing method according to an embodiment of the present invention is not limited to the substrate, but includes any member whose surface is required to be planarized.

### Second Embodiment

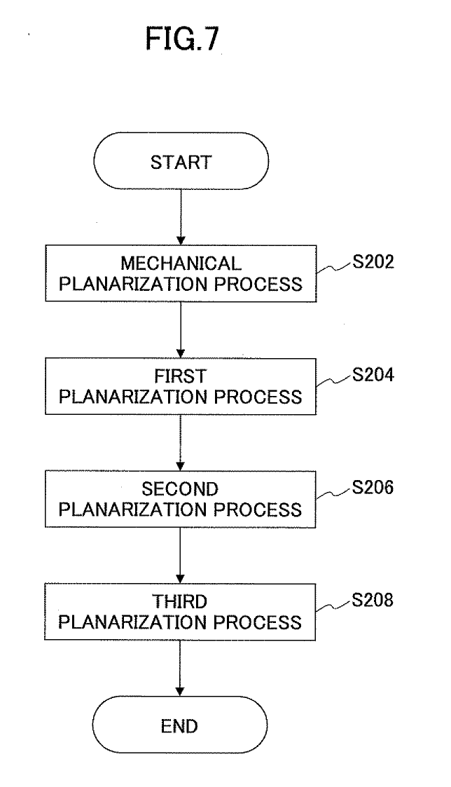

Next, a second embodiment of the present invention is explained with reference to FIG. 7.

First, a surface of a SIC substrate is polished by a CMP process at Step S202, which makes the surface fully planarized to the naked eye. However, countless micro-scratches that cannot be recognized with the naked eye are made in the flat surface of the SiC substrate.

Next, Ar gas clusters are irradiated on the surface of the SiC substrate that has been subject to the CMP process, at Step S204 as a first planarization process. With this, the scratches caused by the CMP process are removed and an extremely flat surface is obtained on the SiC substrate.

Then, nitrogen gas clusters are irradiated to the surface of the SiC substrate that has been subject to the Ar gas cluster irradiation as a second planarization process, at a step S206. With this, the surface of the SiC substrate is further planarized compared to the surface of the SiC substrate after the Ar gas cluster irradiation. Incidentally, an acceleration voltage of the nitrogen gas clusters in the second planarization process is about 20 kV.

Subsequently, the nitrogen gas clusters are irradiated to the surface of the SIC substrate at an acceleration voltage, which is smaller than the acceleration voltage at the first planarization process, of, for example, 10 kV, as a third planarization process. With this, the surface of the SIC substrate is more planarized than the surface of the SIC substrate after the second planarization process. Specifically, when the acceleration voltage is reduced, impact energy of the gas clusters onto the surface of the SIC substrate is reduced. By using such gas clusters, the surface of the SIC substrate is more planarized.

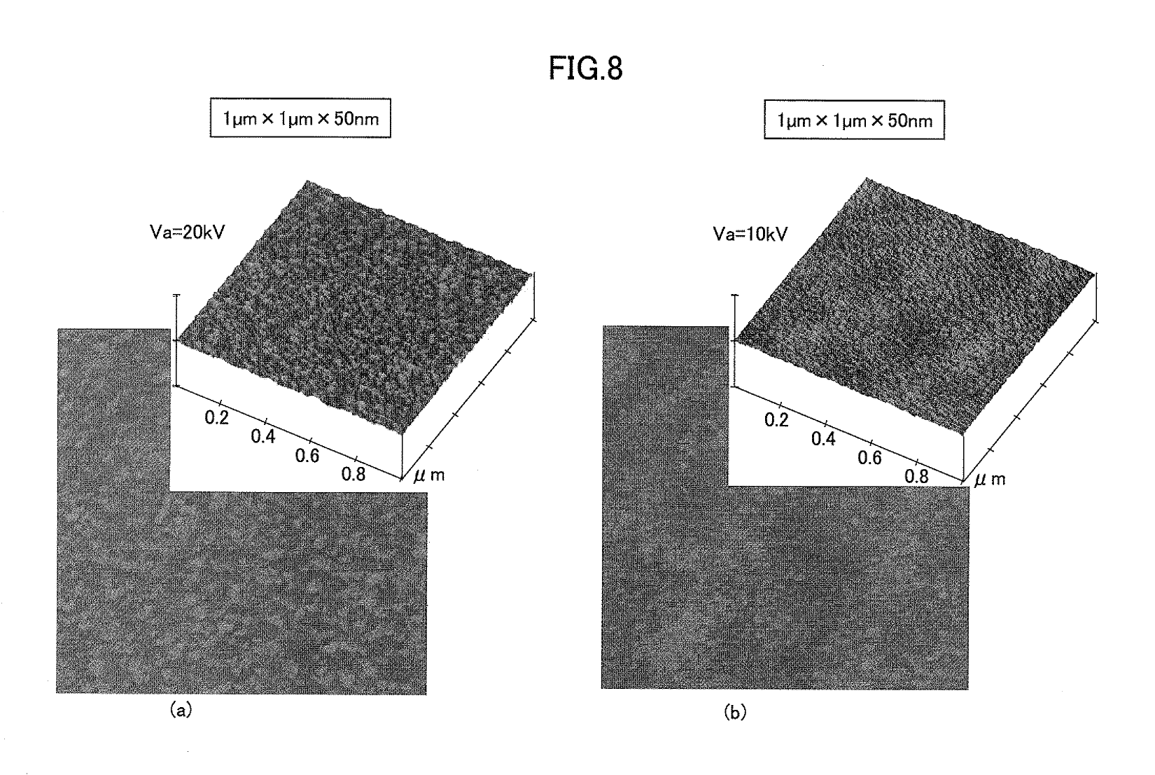

The second planarization process and the third planarization process in this embodiment are further explained with reference to FIG. 8. FIG. 8(a) illustrates an AFM image of the surface of the SIC substrate on which the nitrogen gas clusters are irradiated at the acceleration voltage of 20 kV after the Ar gas cluster irradiation thereon, and FIG. 8(b) illustrates an AFM image of the surface of the SIC substrate on which the nitrogen gas clusters are irradiated at the acceleration voltage of 10 kV after the Ar gas cluster irradiation thereon. It has been found from FIG. 8 that even if the same gas clusters are generated, the gas clusters can planarize the surface of the SiC substrate to a greater degree when being accelerated at a lower acceleration voltage than when being accelerated at a higher acceleration voltage. Therefore, the surface of the SiC substrate can be more planarized according to the surface processing method, which further includes the third planarization process after the second planarization process.

In other embodiments, after the Ar gas clusters are irradiated on the surface of the SiC substrate, nitrogen gas clusters having a first size (in unit of atoms/cluster) are irradiated on the surface of the SiC substrate and then nitrogen gas clusters having a second size that is larger than the first size may be irradiated on the surface of the SiC substrate. According to such a substrate processing method, the surface of the SiC substrate can be planarized because gas clusters having a relatively larger size can improve surface planarity to a greater degree than gas clusters having a smaller size. Incidentally, because gas clusters having a desired size can be selected by adjusting a voltage applied to the electrode portion 41 from the electric power sources 41a, 41b as stated above, the gas clusters having a first size and the gas clusters having a second size larger than the first size are determined, for example, by conducting experiments in advance depending on the member to be planarized and a degree of planarity.

While the present invention has been described with reference to the foregoing embodiments, the present invention is not limited to the disclosed embodiments, but may be modified or altered within the scope of the accompanying claims.

What is claimed is:

1. A surface processing method comprising:
a first processing step, wherein a gas cluster beam is generated from a source material that does not contain nitrogen, and irradiated to a member to be processed, and
a second processing step, wherein a nitrogen gas cluster beam is generated and irradiated to the member to be processed.

2. The surface processing method recited in claim 1, further comprising a chemical mechanical polishing step, wherein a chemical mechanical polishing is carried out prior to the first processing step with respect to the member to be processed.

3. The surface processing method recited in claim 1, wherein the source material that does not include nitrogen comprises one or more of argon, oxygen, carbon dioxide, water, sulfur hexafluoride, nitrogen trifluoride, and xenon.

4. The surface processing method recited in claim 1, wherein the nitrogen gas cluster beam in the second processing step does not include a gas cluster originating from the source material in the first processing step.

5. The surface processing method recited in claim 1, wherein the member to be processed comprises one or more of silicon carbide, silicon, quartz, glass, alumina, sapphire, gallium nitride, gallium arsenide, diamond-like carbon, boron carbide, and poly-crystalline diamond.

6. The surface processing method recited in claim 1, further comprising a third processing step, wherein another nitrogen gas cluster beam is irradiated at a lower acceleration voltage than an acceleration voltage in the second processing step to the member to be processed, after the second processing step.

7. The surface processing method recited in claim 1, further comprising a third processing step, wherein another gas cluster beam that has a gas cluster having a larger size than a size of the nitrogen gas cluster in the nitrogen gas cluster beam in the second processing step is irradiated to the member to be processed, after the second processing step.

8. A surface processing apparatus where a gas cluster beam is irradiated to a member to be processed, the apparatus comprising:
a nozzle that generates the gas cluster beam:
a source gas supplying portion that includes a first gas supplying source that supplies a source material that does not include nitrogen, and a second source gas supplying source that supplies nitrogen gas; and
a control portion that causes the source gas supplying portion to selectively supply the source material and the nitrogen gas, and controls the selected source gas from the source gas supplying portion.

9. The surface processing apparatus recited in claim 8, wherein the source material comprises one or more of argon, oxygen, carbon dioxide, water, sulfur hexafluoride, nitrogen trifluoride, and xenon.

10. The surface processing apparatus recited in claim 8, wherein the nitrogen gas in the second source gas supplying source does not include the source material that does not include nitrogen in the first source gas supplying source.

11. The surface processing apparatus recited in claim 8, wherein the member to be processed comprises one or more of silicon carbide, silicon, quartz, glass, alumina, sapphire, gallium nitride, gallium arsenide, diamond-like carbon, boron carbide, and poly-crystalline diamond.

12. The surface processing apparatus recited in claim 8, further comprising:
an ionizing portion that ionizes the gas cluster beam from the nozzle;
an acceleration portion that accelerates the ionized gas cluster beam;
an acceleration voltage supplying portion that supplies an acceleration voltage to the acceleration portion; and
an acceleration voltage controlling portion that controls the acceleration voltage supplying portion so that the gas cluster beam can be irradiated to the member to be processed at different voltages.

13. The surface processing apparatus recited in claim 9, further comprising:
an electrode portion that selects a gas cluster having a desired size; and
an electric power source that supplies an electric voltage to the electrode portion so that gas cluster beam having a gas cluster having a desired size is selected.
